(19) United States
(12) Patent Application Publication
(10) Pub. No.: US 2023/0155589 A1
(43) Pub. Date: May 18, 2023

(54) CHIP INTERFACE CIRCUIT AND CHIP

(71) Applicant: GIGADEVICE SEMICONDUCTOR (SHANGHAI) INC., Shanghai (CN)

(72) Inventors: Ligang Chen, Shanghai (CN); Hong Hu, Shanghai (CN)

(21) Appl. No.: 17/703,198

(22) Filed: Mar. 24, 2022

(30) Foreign Application Priority Data
Nov. 16, 2021 (CN) 202111353660.4

(51) Int. Cl. H03K 19/0185; G11C 16/30

(52) U.S. Cl. CPC H03K 19/018521; G11C 16/30

(57) ABSTRACT

An improved chip interface circuit and chip are disclosed. The circuit includes: a voltage divider circuit, including a first resistor, a second resistor and a switch; an input gate circuit, including a MOS transistor P1 and a MOS transistor N1; one end of the first resistor is connected to the input terminal, and the drains of P1 and N1 are connected to the first terminal, wherein the first terminal is used to connect the main circuit of the chip, and the switch is turned on when the input terminal receives a high-voltage input voltage. The circuit uses low-voltage transistors combined with a voltage divider circuit to realize the chip interface circuit, thereby achieving good interface speed characteristics, and avoiding the problem that the chip cannot work normally when the operating voltage is low due to the high threshold voltage of the high-voltage transistor.

### CROSS-REFERENCE TO RELATED APPLICATIONS

This application claims priority to a Chinese patent application No. 202111353660.4 filed on Nov. 16, 2021, the disclosure of which is incorporated herein by reference in its entirety.

### TECHNICAL FIELD

The disclosure herein generally relates to the field of chips, and more particularly, to a chip interface circuit and a chip using the same.

### BACKGROUND

In order to ensure the normal operation of a chip, the chip needs to be tested before and after packaging. These high voltages used for testing need to be isolated from a main circuit of the chip that operates under power supply voltage, thereby preventing damage to the main circuit by the high voltage. For this purpose, an interface circuit needs to be provided at the entrance of the conventional circuit. In the design stage, the corresponding interface will use a high-voltage transistor with better withstand voltage characteristics, so as to isolate the test high-voltage to avoid damage to the main circuit of the chip.

As portable electronics become more miniaturized, the operating supply voltages have also become lower, but the external high voltages used for testing and the operating high voltages that need to be monitored remain the same. This makes the threshold voltage of the high-voltage transistor of the interface circuit appear too large relative to the power supply voltage of the chip, resulting in poor interface speed. On some occasions with large process deviation, the threshold voltage may even be close to the power supply voltage, resulting in the failure of the interface to work normally.

Thus, an improved chip interface circuit is needed.

### SUMMARY

A technical problem to be solved by the present disclosure is to provide an improved chip interface circuit, which uses low-voltage transistors in combination with a voltage divider circuit to realize the chip interface circuit. Due to the low threshold voltage of the low-voltage transistors, the interface circuit can still achieve good speed characteristics even at lower supply voltages.

According to a first aspect of the present disclosure, a chip interface circuit is provided, and includes: a voltage divider circuit including a first resistor, a second resistor and a switch, an input gate circuit, including a first PMOS transistor and a first NMOS transistor; wherein, the first resistor has one end connected to the input terminal and another end connected to the first node; the second resistor has one end connected to the first node and another end connected to the second node; the switch has one end connected to the second node and another end grounded; the first PMOS transistor has a source connected to the power supply voltage, a gate connected to the first node, and a drain connected to the first terminal; the first NMOS transistor has a source grounded, a gate connected to the first node, and a drain connected to the first terminal, wherein, the first terminal is used to connect a main circuit of a chip, and the switch is turned on when the input terminal receives a high input voltage.

Optionally, the first PMOS transistor and the first NMOS transistor are low voltage MOS transistors.

Optionally, the switch is a second NMOS transistor having a drain connected to the second node, a gate connected to the second terminal, and a source grounded, and the second terminal provides a turn-on voltage for the second NMOS transistor when the input terminal receives the high input voltage.

Optionally, the second NMOS transistor is a low voltage MOS transistor.

Optionally, the high input voltage is V_{PAD}, the resistance value of the first resistor is R1, the resistance value of the second resistor is R2, and the withstand voltage value of the first PMOS transistor and the second NMOS transistor is greater than the value of V_{PAD}*R2/(R2+R1).

Optionally, the input terminal is connected to at least one of the following: a pad connected to an external pin of the chip; an electrostatic discharge circuit; and a high voltage input and output gating circuit.

Optionally, the high input voltage includes at least one of the following: an external test high voltage input by the external pin of the chip via the pad; and a high internal voltage generated by an on-chip charge pump.

Optionally, the input terminal is connected to an external high test voltage input from a chip select pin, and the external high test voltage is provided to a memory cell array via the high voltage input and output gating circuit that is turned on.

According to a second aspect of the present disclosure, a chip is provided, which includes the chip interface circuit according to the first aspect of the present disclosure. Optionally, the chip is a flash memory chip including a charge pump.

Thus, the chip interface circuit of the present disclosure can realize an input gate circuit composed of low-voltage tubes by introducing a voltage divider branch. The voltage divider branch can be turned on during high-voltage testing, and the resistance ratio in the voltage divider circuit can be selected to ensure that the voltage on the MOS transistor does not exceed the withstand voltage of the low-voltage transistor. As a result, better low-voltage characteristics can be achieved, and it is especially suitable for low-operating voltage chips whose operating voltage is close to the threshold voltage of high-voltage transistors.

### BRIEF DESCRIPTION OF FIGURES

Through reading the detailed description of the embodiments below, various other advantages and benefits will become apparent to the person having ordinary skill in the art. The drawings are only for the purpose of illustrating the embodiments described below and are not intended to limit the present disclosure. Throughout the drawings, the same reference number refers to the same part. In the drawings:

FIG. 1 illustrates a simplified schematic diagram of a system including a memory chip according to one embodiment of the present disclosure.

FIG. 2 illustrates an example of a top view of an 8-pin memory chip.

FIG. 3 illustrates an example of a chip interface circuit.

FIG. 4 illustrates an example of a high voltage input and output gating circuit for a memory chip.

FIG. 5 illustrates a schematic diagram of the composition of a chip interface circuit according to an embodiment of the present disclosure.

### DETAILED DESCRIPTION

Embodiments of the present disclosure will be described in more detail below with reference to the accompanying drawings. While exemplary embodiments of the present disclosure are shown in the drawings, it should be understood that the present disclosure may be embodied in various forms and should not be limited by the embodiments set forth herein. Rather, these embodiments are provided so that this disclosure will be thorough and complete, and will fully convey the scope of the disclosure to those skilled in the art.

Various embodiments will be described in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the disclosure to those skilled in the art. In the present disclosure, the same reference numerals refer to the same parts throughout the various figures and embodiments of the present disclosure.

It should be noted that the drawings are simplified schematic diagrams and therefore not necessarily drawn to scale. In some instances, parts of the figures may have been exaggerated in order to more clearly illustrate certain features of the illustrated embodiments.

It is further noted that in the following description, specific details are set forth in order to facilitate an understanding of the present disclosure, however, the present disclosure may be practiced without some of these specific details. Additionally, it is noted that well-known structures and/or procedures may only be described briefly or not at all in order to avoid obscuring the disclosure with unnecessary detail.

It should also be noted that, in some cases, elements (also referred to as features) associated with one embodiment described may be used alone or in conjunction with another embodiment, unless specifically stated otherwise, as apparent to those skilled in the relevant art. used in combination with other components. In addition, the following uses of “first”, “second” and even “third” are intended to distinguish different objects of the same category for the convenience of description, rather than implying importance or sequence.

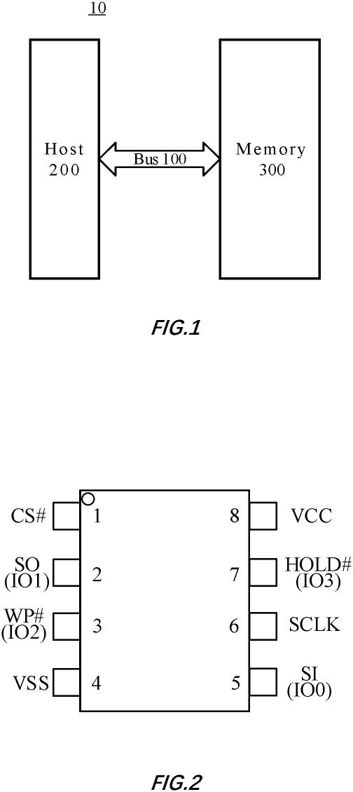

Various embodiments of the present disclosure will be described in detail below with reference to the accompanying drawings, and for ease of understanding, the use environment of the chip in the present disclosure will be described first with reference to FIG. 1.

FIG. 1 illustrates a simplified schematic diagram of a system including a memory chip according to one embodiment of the present disclosure. The system 10 may be implemented as an electronic device, and the device 10 may include a host 200 and a memory 300 as shown and communicate via a bus 100.

Here, the host 200 refers to a part that implements the key functions of the device 10, that is, the main part of the device 10, and the host 200 (or the device 10) can be any electronic device. In one embodiment, device 10 may be an electronic device including, but not limited to, for example, portable electronic devices such as mobile phones, tablet computers, wearable devices (e.g. TWS headsets) and laptop computers; or non-portable electronic devices, such as desktop computers, game consoles, televisions, set-top boxes, and projectors; it could even be industrial loT devices such as individually set up sensors. In this case, the memory 300 may be a device that provides storage services for the stand-alone electronic device.

In other embodiments, the device 10 may also be an electronic component with a relatively independent function (these electronic components are usually key components constituting an electronic device), such as a separately sold smart screen, a main control chip, a camera assembly, etc. These electronic components usually need to be assembled, for example, a smart screen is assembled to a mobile phone, in order to provide services to a consumer (e.g., a user who purchase the mobile phone). In this case, the memory 300 may be a part that provides necessary storage services for electronic components.

Here, the host 200 may be implemented as or include a microcontroller, a microprocessor, an application specific integrated circuit (ASIC), or an application specific standard product (ASSP), and is coupled to the memory 300 as a slave device via the bus 100 as shown. Here, the bus 100 is shown as a bidirectional arrow connected between the host 200 and the memory 300 to indicate bidirectional information transfer between the host 200 and the memory 300 via the bus.

In one embodiment, the bus 100 may be implemented as an interface bus, such as a Serial Peripheral Interface (SPI) bus and may actually include multiple connecting lines to enable the transfer of instructions, addresses, and data. For this reason, communication between different chips for realizing various functions in the host 200 and between the host 200 and the memory chip 300 can be performed via the bus 100. The plurality of connection lines included in the bus 100 may be connected to interfaces provided by both the host 200 and the memory 300, and the host 200 and the memory 300 may each include pins for realizing the above connections.

In a preferred embodiment, the memory 300 may be implemented as a flash memory device with an SPI interface, particularly NOR flash and NAND flash, and capable of sequential access to data via a serial interface (i.e., via pins) and suitable for applications such as voice, image, program code and data storage and many other applications. Specifically, the memory 300 can be enabled by a chip strobe signal received on a chip select (CS) pin (e.g., a specified active “assertion” signal), and data access can be made via a data input (SI) pin, a data output (SO) pin, and a clock (CLK) pin.

FIG. 2 illustrates an example of a top view of an 8-pin memory chip. As shown, the memory chip is an SOP packaged chip and has 8 pins. Pin 1, Pin 5, Pin 2 and Pin 6 correspond to the above chip select (CS) pin, the data input (SI) pin, the data output (SO) pin, and the clock (CLK) pin. Pin 1 is shown as “CS#”, where “#” is used to indicate that the signal is active low. Further, Pin 6 is shown as “SCLK”, where the “S” before “CLK” is used to indicate that the signal is the system clock from the outside, in order to distinguish it from an “internal clock” inside the memory.

For normal operation, the memory 300 may include a power interface for receiving external power, such as pin 8 shown in FIG. 2, that is, a pin for receiving an external voltage VCC (e.g., a first voltage). This pin may, for example, obtain power supply from a power supply device of the system (e.g., the electronic device 10). Further, the memory 300 may further include a pin connected to the system ground, such as pin 4 for grounding and providing the ground voltage VSS. The memory chip may also include pin 3 (write-protect WP) and pin 7 (HOLD).

Further, in different data transmission modes, some pins of the chip can be multiplexed as IO pins. The SI pin, SO pin, WP pin, and HOLD pin can be used as the IO0^{~}IO3 pins shown in parentheses in FIG. 2 in the “Quad SPI” mode of the memory chip, thereby enabling the memory chip to send and receive data four times faster in conventional mode.

In addition, although the memory chip shown in FIG. 2 is an SOP packaged chip with 8 pins, it should be understood that the principles of the present disclosure are equally applicable to memory chips of other package types, such as SON and FBGA packaged chips, and the host 200 can also be connected to the corresponding pad terminals or solder microspheres of these chips via the bus 100. The external ports of these chips (e.g., pad terminals or solder balls) can also be considered as pins of memory chips. In other words, the present disclosure does not limit the port form of the memory chip.

In addition to a main circuit that realizes its design function, a chip also has other modules and interface circuits to ensure the normal operation of the chip. FIG. 3 illustrates an example of a chip interface circuit. The chip interface circuit can be used as an interface circuit of various types of chips, especially can be used as a chip interface circuit of the memory chip 300 shown in FIG. 1.

For the convenience of understanding, the meanings of “pad”, “pin”, “port” and “terminal” used in the present disclosure are described herein. The NET (circuit network) inside the chip needs to be led to the outside of the chip for packaging, but because the width of the metal wire is too thin to withstand the pressure of welding, it needs to be connected to a large metal block first, with the large metal block as a support. This large piece of metal under pressure can be called a “pad”. The signal input and output ports and pads in the chip are led to the outside of the chip, and as a whole, can be collectively referred to as “pins” of the chip, such as 8 protruding pins shown in FIG. 2. In SON and FBGA packages, the pads shown in FIG. 3 can also be equated with pad terminals or solder balls that the chip uses to exchange signals with the outside world, and both “pins” and pad terminals or solder balls can be considered as “ports” that the chip uses to exchange information with the outside. Regardless of the implementation, the pads are connected to the ports where the chip communicates with the outside world. The input/output of each circuit module inside the chip, such as the PIN in FIGS. 3-5, can be called a terminal.

Here, although not shown in the figure, it can be considered that the PAD is a port that directly exchanges information with outside or is directly connected to pins extending from the chip. PIN2 is connected to the main circuit of the chip. In the case where the chip is a memory chip, the main circuit of the chip may refer to a circuit mainly implemented on a silicon chip for realizing the function of the memory, for example, it may include a memory cell array, a charge pump, an addressing unit, a control logic circuit and various registers.

As shown in FIG. 3, before the signal introduced from the PAD enters the main circuit of the chip through PIN2, there are also a high voltage input and output gating circuit 310 branch and an ESD circuit 320 branch, and it needs to pass through an input gate 330 composed of high-voltage transistors.

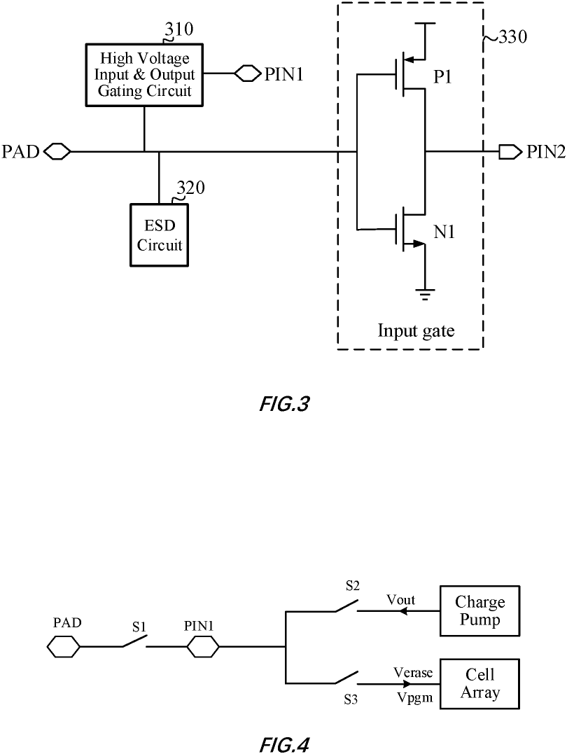

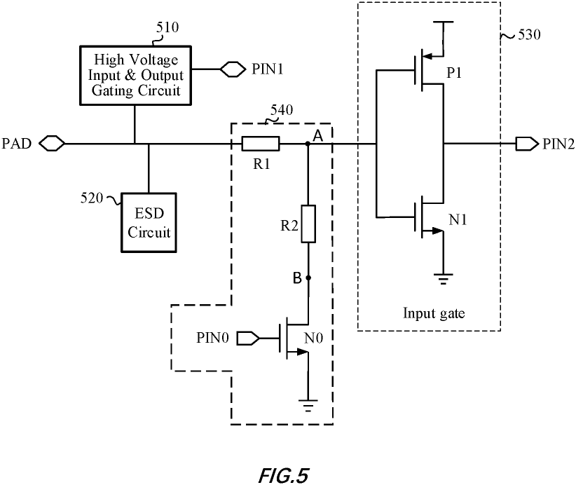

In order to ensure the normal operation of the chip, the chip needs to be tested before and after packaging. This requires the high voltage input and output gating circuit 310 to transmit the external high voltage used for testing to the circuit that needs to receive the external high voltage, and to lead out the operating high voltage to be monitored. FIG. 4 illustrates an example of a high voltage input and output gating circuit for a memory chip. The memory chip may be a flash memory chip such as NAND or NOR. Due to the unique floating gate design used in flash memory chips, high voltages are required to send electrons to and from the floating gate during erase and write operations, so the memory chip needs to include a charge pump circuit to generate the operation high voltage, such as erase high voltage Verase and program (write) high voltage Vpgm. Here, the “high voltage” is relative to the maximum withstand voltage of low voltage MOS transistors. For example, the “high voltage” may be an operating voltage that is three times, five times, or even ten times the chip operating voltage.

During the normal operation of the chip (that is, in the use mode of the chip), such as during the normal erasing or writing operation of the chip, the erase high voltage Verase and the programming high voltage Vpgm can be directly generated by the charge pump, and can be used to erase or write data in the memory cell array. However, during the chip test (i.e., in the test mode of the chip), it is necessary to separately test the generation of the operating voltage of the charge pump and the operation of the memory cell array under the corresponding voltage. For this reason, as shown in FIG. 4, the switch S1 needs to be kept closed during the high voltage operation test. When monitoring the operating high voltage generated by the charge pump, the switch S2 is closed, so that PIN1 can be connected to the output of the charge pump, and test whether the operating voltage Vout generated by the charge pump meets the test requirements. For example, an oscilloscope can be connected to the PAD, and when S1 and S2 are closed (and under the corresponding charge pump control command), the operating voltage Vout of the charge pump can be read, so that it can be judged whether the charge pump is working normally according to the waveform on the oscilloscope. When an external voltage is applied, a high voltage can be applied via the PAD. At this time, S3 is closed, and PIN1 is connected to the memory cell array, thereby testing the memory cell array under the corresponding erasing high voltage Verase and programming high voltage Vpgm (and under the corresponding erasing or writing control command) whether erasing and writing can be realized normally. In other words, the switch S1 in FIG. 4 can be regarded as the high voltage input and output gating circuit 310 shown in FIG. 3, or the combination of switches S1, S2 and S3 is collectively regarded as the high voltage input and output gating circuit 310. Due to the need to withstand high voltages, switches S1, S2 and S3 can all be implemented by high voltage transistors. In addition, although FIG. 4 shows an example of connecting the charge pump to output high voltage and connecting the memory array unit to input high voltage, in other embodiments, for example, in other chips other than the memory chip, PIN1 can also be connected to different circuits, such as other circuits that need to output high voltage, or receive input to test high voltage. The present disclosure does not limit this.

Another branch shown in FIG. 3, the ESD circuit 320, is a protection circuit designed for electrostatic discharge (ESD: Electrostatic Discharge). The static electricity accumulated in the human body, instrument or equipment during the process of chip production, assembly, testing, storage, handling, etc., and even the static electricity accumulated in the components, will form a discharge path when certain objects come into contact. Due to very high transient voltages (> several thousand volts), electrostatic discharge can cause irreversible damage to electronic components or systems, making prevention of electrostatic damage a must for all IC design and manufacturing. For example, a typical ESD circuit can be implemented using a clamping diode in series with a high resistor. The reverse cut-off characteristic of the clamping diode makes the ESD branch in a disconnected state during normal operation, and avalanche breakdown occurs when there is static electricity outside to form a bypass path to protect the main circuit of the chip. Because static electricity needs to be discharged immediately, the ESD module is usually placed next to the PAD at the input terminal of the chip, not inside the chip (for example, it cannot be placed behind PIN2).

Whether it is the high voltage for measurement gated by the circuit 310, or the bypass path for electrostatic discharge formed by the ESD circuit, it needs to be isolated from the chip main body circuit that operates under the power supply voltage in the chip, thereby preventing the main body circuit from being damaged by high voltages. In view of this, it is necessary to connect the input gate at the entrance of the conventional circuit, that is, in front of PIN2. In the present disclosure, the high voltage input and output gating circuit 310, the ESD circuit 320 and the input gate 330 may be collectively referred to as a chip interface circuit. The circuits used to connect the high-voltage bypass (310 and 320 in FIG. 3) with various types of internal chip main circuits can also be referred to as “chip interface circuits” separately. In other words, the input gate composed of a PMOS transistor P1 and an NMOS transistor N1 can be regarded as a “chip interface circuit” in FIG. 3. (In addition, although it is not shown in the figure, it should be understood that P1 and N1 essentially constitute an inverter, so another inverter can be connected later, so that the input signal remains unchanged. But this inverter does not need It is used for high-voltage isolation, so it can be realized by common low-voltage transistors, or even in the internal circuit of the chip, so it is omitted in the description of the chip interface circuit used for high-voltage isolation in the present disclosure.)

As previously mentioned in conjunction with shown in FIG. 4, high voltage can be input from PAD when testing, through high voltage input and output gating circuit S1, this external input high voltage can be sent to the inside of memory chip through PIN1; When monitoring the internal operating high voltage, the internal high voltage is sent to the PAD from PIN1 through the high voltage input and output strobe circuit S1. Regardless of the high voltage input or internal high voltage monitoring, the high voltage on the PAD will be sent to the gates of the input gate MOS transistors P1 and N1. In order to prevent P1 and N1 from being broken down, high-voltage transistors with better withstand voltage characteristics are selected in the design, that is, P1 and N1 need to be implemented by high-voltage transistors.

As portable electronics become more and more miniaturized, the operating supply voltages have also become lower, but the external high voltages used for testing and the operating high voltages that need to be monitored remain the same. This makes the threshold voltage of the high-voltage tube of the interface circuit appear too large relative to the power supply voltage of the chip, resulting in poor interface speed. In view of this, the present disclosure provides an improved chip interface circuit, which uses a low-voltage transistor combined with a voltage divider circuit to realize the chip interface circuit. Since the threshold voltage of the low-voltage transistor is low, even if the chip operates at a lower power supply voltage, the interface circuit can still achieve excellent speed characteristics.

FIG. 5 illustrates a schematic diagram of the composition of a chip interface circuit according to an embodiment of the present disclosure. As shown in the figure, between the PAD (serving as an external input and output port) and the terminal PIN2 for connecting the main circuit of the chip, a high voltage input and output gating circuit 510 and an ESD circuit 520 are still included. These two branches can be considered the same as circuits 310 and 320 shown in FIG. 3. Further, the chip interface circuit of the present disclosure may also include an input gate circuit 530 and a voltage divider circuit 540.

Specifically, the input gate circuit 530 includes a first PMOS transistor P1 and a first NMOS transistor N1. Different from the high voltage transistors P1 and N1 shown in FIG. 3, the P1 and N1 shown in FIG. 5 may be implemented by low voltage transistors. In FIGS. 3 and 5, both P1 and N1 (and N0 included in FIG. 5) are logic transistors that function as switches, not power transistors. Therefore, “high voltage transistor” and “low voltage transistor” here refer to the relatively high and low withstand voltage of the transistor.

The reason why P1 and N1 can be realized by low-voltage transistors is that a voltage divider circuit is provided. The voltage divider circuit 540 includes a resistor R1 (which may also be referred to as a “first resistor”), a resistor R2 (which may also be referred to as a “second resistor”), and a switch. In the example of FIG. 5, the switch may be implemented by a second NMOS transistor N0. Similarly, the transistor N0 used as a switch can also be realized by a low voltage transistor.

As shown in the figure, one end of the resistor R1 is connected to the input terminal, that is, the PAD, and the other end is connected to the node A (also referred to as the “first node”). One end of the resistor R2 is connected to the node A, that is, connected to one end of the resistor R1; the other end is connected to the node B (also known as the “second node”. One end of the switch is connected to the node B, that is, connected to one end of the resistor R2; the other end is grounded.

The source of P1 is connected to the power supply voltage, the gate is connected to node A, and the drain is connected to the first terminal, namely PIN2; the source of N1 is grounded, the gate is connected to node A, and the drain is connected to PIN2. In other words, P1 and N1 are inverters whose gates are interconnected, and their drains are also interconnected (As mentioned above, P1 and N1 essentially constitute an inverter, so another inverter can be connected later to make the input signal unchanged. But the inverter does not need to be used for high-voltage isolation and can be implemented by common low-voltage transistors, or even implemented in the internal circuit of the chip, so the inverter is omitted in the description of the chip interface circuit for high-voltage isolation in the present disclosure).

PIN2 is used to connect the main circuit of the chip, and the switch can be turned on when the PAD receives a high-voltage input voltage. Here, the PAD receives a high-voltage input voltage, which means that the left side of R1 in the figure receives a high-voltage. This input voltage can be input from the outside for testing the internal circuit, for example, the high voltage can be input by the external pins of the chip used to test the memory cell array. It can also be output to the PAD by the internal voltage (it can also be regarded as the input high voltage received on the PAD), such as the internal operating high voltage generated by the charge pump in the chip. In one embodiment, the PAD can access the external test high voltage input by the chip select pin (for example, the first pin CS shown in FIG. 2), and pass the external test high voltage through the connected high voltage input and output gating circuit (e.g., switch S1 that is turned on) is provided to the memory cell array.

When the switch is implemented by N0, the drain of N0 is connected to node B, the gate is connected to the second terminal (i.e., PIN0), and the source is grounded. PIN0 can provide the ON voltage for the N0 when the input voltage is high. For example, PIN0 can be set to provide a continuous on-voltage input for the gate of N0 when the high voltage input and output gating circuit 510 is turned on. Thus, it is ensured that the voltage divider branch (the path from node A to R2, N0 and ground) only works when the high voltage input and output gating circuit 510 is turned on, and during other periods (e.g., in the normal use mode of the chip), Since the N0 gate has no voltage input, the voltage divider branch is disconnected, which will not affect the normal operation of the main circuit of the chip.

Specifically, during the test, when the PAD needs to input or output a high voltage, the switching transistor N0 is turned on, and the voltage is divided by R1/R2, and the node A voltage=V(PAD)*R2/(R1+R2). The resistance ratio of R1 and R2 can be selected, so that the voltage of node A is within the withstand voltage range of low-voltage transistors P1 and N0, which can effectively prevent the low-voltage transistor from being broken down, improve the interface input speed, and prevent the power supply voltage from failing to work. In the normal use stage, the switching transistor N0 is turned off, which does not affect the normal input of the signal.

Thus, by introducing a voltage divider circuit, a solution in which the interface adopts a low-voltage transistor design is realized. Compared with the high-voltage transistor, the low-voltage MOS transistor has a smaller threshold voltage, can work at a lower power supply voltage, and has good speed characteristics. Input gate implemented by low-voltage transistors can also achieve better interface speeds and prevent inoperability at low supply voltages.

While the present disclosure is particularly applicable to interface circuits implemented as low supply voltage chips, it is equally applicable to high supply voltage chips. This is because at high power supply voltages, although the high-voltage transistors in the prior art can work normally, their speed characteristics are poor. Using the chip interface circuit of the present disclosure realizes the use of low-voltage transistors through a voltage divider circuit and can achieve better speed characteristics.

Further, the present disclosure can also be implemented as a chip, and the chip includes a chip interface circuit as described above. The chip may in particular be a flash memory chip including a charge pump, and in the structure shown in FIG. 1, serves as a memory 300 for the host 200 to provide a storage function. In other embodiments, the present disclosure can also be implemented as other chips that need to be connected to high voltage during testing. For example, the present disclosure may also be implemented as a chip implementing various other functions in the host 200 shown in FIG. 1.

The chip interface circuit according to the present disclosure has been described in detail above with reference to the accompanying drawings. The chip interface circuit of the present disclosure realizes an input gate circuit composed of low-voltage transistors by introducing a voltage divider circuit. The voltage divider branch can be turned on during high-voltage testing, and the resistance ratio in the voltage-dividing circuit can be reasonably selected to ensure that the voltage on the MOS transistor does not exceed the withstand voltage of the low-voltage transistor. As a result, better low-voltage characteristics can be achieved, and it is especially suitable for low-operating voltage chips whose operating voltage is close to the threshold voltage of high-voltage transistors.

Various embodiments of the present disclosure have been described above, and the foregoing descriptions are exemplary, not exhaustive, and not limiting of the disclosed embodiments. Numerous modifications and variations will be apparent to those of ordinary skill in the art without departing from the scope and spirit of the described embodiments. The terminology used herein was chosen to best explain the principles of the embodiments, the practical application or improvement over the technology in the marketplace, or to enable others of ordinary skill in the art to understand the embodiments disclosed herein.

What is claimed is:

1. A chip interface circuit, comprising:
a voltage divider circuit including a first resistor, a second resistor and a switch,
an input gate circuit, including a first PMOS transistor and a first NMOS transistor;
wherein, the first resistor has one end connected to the input terminal and another end connected to the first node; the second resistor has one end connected to the first node and another end connected to the second node; the switch has one end connected to the second node and another end grounded; the first PMOS transistor has a source connected to the power supply voltage, a gate connected to the first node, and a drain connected to the first terminal; the first NMOS transistor has a source grounded, a gate connected to the first node, and a drain connected to the first terminal,
wherein, the first terminal is used to connect a main circuit of a chip, and the switch is turned on when the input terminal receives a high input voltage.

2. The chip interface circuit of claim 1, wherein the first PMOS transistor and the first NMOS transistor are low voltage MOS transistors.

3. The chip interface circuit of claim 2, wherein the switch is a second NMOS transistor having a drain connected to the second node, a gate connected to the second terminal, and a source grounded, and the second terminal provides a turn-on voltage for the second NMOS transistor when the input terminal receives the high input voltage.

4. The chip interface circuit of claim 3, wherein the second NMOS transistor is a low voltage MOS transistor.

5. The chip interface circuit of claim 3, wherein the high input voltage is V_{PAD}, the resistance value of the first resistor is R1, the resistance value of the second resistor is R2, and the withstand voltage value of the first PMOS transistor and the second NMOS transistor is greater than the value of V_{PAD}^{∗}R2/(R2+R1).

6. The chip interface circuit of claim 1, wherein the input terminal is connected to at least one of the following:
a pad connected to an external pin of the chip;
an electrostatic discharge circuit; and
a high voltage input and output gating circuit.

7. The chip interface circuit of claim 6, wherein the high input voltage includes at least one of the following:
an external test high voltage input by the external pin of the chip via the pad; and
a high internal voltage generated by an on-chip charge pump.

8. The chip interface circuit according to claim 6, wherein the input terminal is connected to an external high test voltage input from a chip select pin, and the external high test voltage is provided to a memory cell array via the high voltage input and output gating circuit that is turned on.

9. A chip, comprising a chip interface circuit, wherein the chip interface circuit comprises:
a voltage divider circuit including a first resistor, a second resistor and a switch,
an input gate circuit, including a first PMOS transistor and a first NMOS transistor;
wherein, the first resistor has one end connected to the input terminal and another end connected to the first node; the second resistor has one end connected to the first node and another end connected to the second node; the switch has one end connected to the second node and another end grounded; the first PMOS transistor has a sourceconnected to the power supply voltage, a gate connected to the first node, and a drain connected to the first terminal; the first NMOS transistor has a source grounded, a gate connected to the first node, and a drain connected to the first terminal,
wherein, the first terminal is used to connect a main circuit of a chip, and the switch is turned on when the input terminal receives a high input voltage.

10. The chip of claim 9, wherein the first PMOS transistor and the first NMOS transistor are low voltage MOS transistors.

11. The chip of claim 10, wherein the switch is a second NMOS transistor having a drain connected to the second node, a gate connected to the second terminal, and a source grounded, and the second terminal provides a turn-on voltage for the second NMOS transistor when the input terminal receives the high input voltage.

12. The chip of claim 11, wherein the second NMOS transistor is a low voltage MOS transistor.

13. The chip of claim 11, wherein the high input voltage is V_{PAD}, the resistance value of the first resistor is R1, the resistance value of the second resistor is R2, and the withstand voltage value of the first PMOS transistor and the second NMOS transistor is greater than the value of V_{PAD}^{∗}R2/(R2+R1).

14. The chip of claim 9, wherein the input terminal is connected to at least one of the following:
a pad connected to an external pin of the chip;
an electrostatic discharge circuit; and
a high voltage input and output gating circuit.

15. The chip of claim 14, wherein the high input voltage includes at least one of the following:
an external test high voltage input by the external pin of the chip via the pad; and
a high internal voltage generated by an on-chip charge pump.

16. The chip of claim 14, wherein the input terminal is connected to an external high test voltage input from a chip select pin, and the external high test voltage is provided to a memory cell array via the high voltage input and output gating circuit that is turned on.

17. The chip of claim 9, wherein the chip is a flash memory chip including a charge pump.
